(19) United States
(12) Patent Application Publication
(10) Pub. No.: US 2026/0362553 A1
(43) Pub. Date: Nov. 12, 2026

(54) HEAT TRANSFER ASSEMBY FOR USE IN A PROCESSING CHAMBER

(71) Applicant: Applied Materials, Inc., Santa Clara, CA (US)

(72) Inventors: Neil WARKE, Santa Clara, CA (US); Kim Ramkumar VELLORE, San Jose, CA (US); Benjamin Ean THAM, Elk Grove, CA (US)

(21) Appl. No.: 19/202,708

(22) Filed: May 8, 2025

(51) Int. Cl. H05B 3/00; F28D 15/02; H10P 72/00

(52) U.S. Cl. CPC H05B 3/0038; F28D 15/02; H10P 72/0436

(57) ABSTRACT

Embodiments of the present invention generally relate to a heat transfer assembly for use in a semi-conductor processing chamber. In one or more embodiments, a processing chamber includes a housing structure. An upper window and a lower window are disposed within the housing structure. The upper window and the lower window at least partially define a processing volume. A reflector is disposed within the housing structure outside of the processing volume. A heat transfer assembly is disposed outwardly of an annular portion of the reflector. The heat transfer assembly includes a lower structure disposed on a base portion of the reflector. An upper structure is disposed on the lower structure. One or more heat pipes are disposed within the upper structure, the lower structure, or a combination thereof. A heat sink is coupled to the one or more heat pipes. One or more heating lamps contact the heat transfer assembly.

### BACKGROUND

### Field

Embodiments of the present invention generally relate to a heat transfer assembly for use in a semi-conductor processing chamber, and related components.

### Description of the Related Art

Heating lamps are disposed within semiconductor processing chambers in order to provide thermal energy to heat substrates and/or process gases used in a processing operation. These lamps emit radiation that increases the temperature of materials involved in processes such as chemical vapor deposition (CVD), rapid thermal processing (RTP), or an epitaxial deposition process. By directing heat without physical contact, heating lamps offer fast response times and temperature control, which is used to maintain uniformity and efficiency during fabrication steps. However, because these lamps can generate intense heat, there is a risk of the lamps overheating and getting damaged.

To manage this excess heat, cooling channels are integrated into the chamber design to help regulate temperature of the lamps. These channels typically circulate a coolant fluid to absorb and carry away excess thermal energy. However, cooling channels can sometimes leak within the processing chamber. If a cooling channel leaks, it can introduce moisture or other contaminants into the processing environment, disrupting operations and potentially damaging both the equipment and the semiconductor materials.

Therefore, a need exists for improved heat transfer assembly for use in semi-conductor processing.

### SUMMARY

Embodiments of the present invention generally relate to a heat transfer assembly for use in a semi-conductor processing chamber, and related components.

In one or more embodiments, a processing chamber includes a housing structure. An upper window and a lower window are disposed within the housing structure. The upper window and the lower window at least partially define a processing volume. A reflector is disposed within the housing structure outside of the processing volume. A heat transfer assembly is disposed outwardly of an annular portion of the reflector. The heat transfer assembly includes a lower structure disposed on a base portion of the reflector. An upper structure is disposed on the lower structure. One or more heat pipes are disposed within the upper structure, the lower structure, or a combination thereof. A heat sink is coupled to the one or more heat pipes. One or more heating lamps contact the heat transfer assembly.

In one or more embodiments, a heat transfer assembly includes a lower structure including an annular base. A plurality of lower extension structures extend from the annular base. The heat transfer assembly further includes an upper structure including an annular base. A plurality of upper extension structures extend from the annular base; The heat transfer assembly further includes one or more heat pipes including an annular portion disposed within the annular base of the lower structure, the annular base of the upper structure, or a combination thereof. An extension portion is disposed outwardly of the lower structure, the upper structure, or a combination thereof. A heat sink is coupled to the extension portion.

In one or more embodiment, a processing chamber includes a housing structure. An upper window and a lower window are disposed within the housing structure. The upper window and the lower window at least partially define a processing volume. A reflector is disposed within the housing structure outside of the processing volume. A heat transfer assembly is disposed outwardly of an annular portion of the reflector. The heat transfer assembly includes a lower structure including an annular base and a plurality of lower extension structures extending from the annular base. An upper structure includes an annular base and a plurality of upper extension structures extending from the annular base. One or more heat pipes include an annular portion disposed within the annular base of the lower structure, the annular base of the upper structure, or a combination thereof. An extension portion is disposed outwardly of the lower structure, the upper structure, or a combination thereof. A heat sink is coupled to the extension portion. One or more heating lamps contact the heat transfer assembly.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, and may admit to other equally effective embodiments.

FIG. 1 is a schematic cross-sectional view of a processing system, according to one or more embodiments.

FIG. 2A is a schematic isometric view of an upper structure, according to one or more embodiments.

FIG. 2B is a schematic isometric view of a lower structure, according to one or more embodiments.

FIG. 3 is a schematic isometric view of a heat pipe, according to one or more embodiments.

FIG. 4 is a schematic isometric view of a heat sink, according to one or more embodiments.

FIG. 5 is a schematic isometric view of a heating lamp, according to one or more embodiments.

FIG. 6 is a schematic isometric view of a heat transfer assembly disposed on an outer reflector, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to a heat transfer assembly for use in a semi-conductor processing chamber, and related components. In one or more embodiments, the heat transfer assembly includes an upper structure, a lower structure, one or more heat pipes, and a heat sink. The one or more heat pipes are at least partially embedded within the upper structure, the lower structure, or a combination thereof. In one or more embodiments, the one or more heat pipes include an outer shell defining a vacuum-sealed volume and a heat transfer fluid disposed within the vacuum-sealed volume. The heat pipes are configured to cool one or more heating lamps within the processing chamber in order to prevent the one or more heating lamps from overheating.

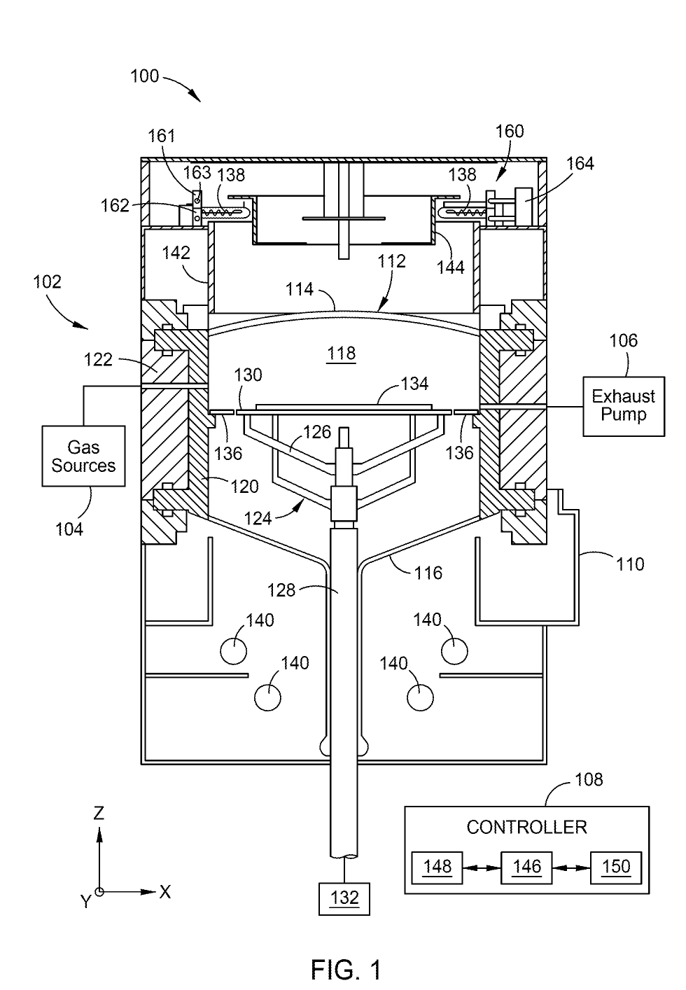

FIG. 1 is a schematic cross-sectional view of a processing system 100, according to one or more embodiments. The processing system 100 can be configured to perform epitaxial deposition. While a processing system for performing epitaxial processes is shown and described herein, the inventive aspects of the present disclosure are also applicable to other processing systems capable of providing a controlled thermal cycle that heats a substrate for processes such as, for example, thermal annealing, thermal cleaning, thermal chemical vapor deposition, thermal oxidation, and thermal nitridation.

As shown in FIG. 1, the processing system 100 includes a process chamber 102, one or more gas sources 104, an exhaust pump 106, and a controller 108. For reference, the processing system 100 defines a first direction X, a second direction Y, and a third direction Z, which are mutually perpendicular to one another and form an orthogonal direction system. In at least some embodiments, the first direction X can be a lateral direction, the second direction Y can be a transverse direction, and the third direction Z can be a vertical direction.

The process chamber 102 includes a housing structure 110 made of a process resistant material, such as aluminum or stainless steel, for example 316L stainless steel. The housing structure 110 encloses various functioning elements of the process chamber 102, such as a quartz chamber 112. The quartz chamber 112 includes an upper window 114 such as an upper dome and a lower window s such as a lower dome. The quartz chamber 112 encloses a process volume 118. One or more plates 120, 122 can form the sides of the quartz chamber 112.

The process chamber 102 also includes a substrate support assembly 124. The substrate support assembly 124 can include supports 126 and a shaft 128. A susceptor 130 can be positioned on the supports 126. The substrate support assembly 124 can further include an actuator 132 to rotate the shaft 128 and the susceptor 130. A substrate 134 can be positioned on the susceptor 130 during processing, such as during epitaxial deposition.

Gases can be provided to the process volume 118 from the gas sources 104 during deposition and other processes. These gases can be exhausted from the process volume 118 by the exhaust pump 106. The process chamber 102 can further include a preheat ring 136 that can be positioned around the susceptor 130.

The process chamber 102 can also include upper heating lamps 138 and lower heating lamps 140 for heating the substrate 134 and/or the process volume 118. In at least some embodiments, the upper heating lamps 138 and/or the lower heating lamps 140 can be infrared (IR) or radiant heat lamps, such as tungsten halogen lamps. The upper and lower heating lamps 138, 140 can provide heat to the substrate 134 though the upper window 114 and the lower window 116, respectively. The upper and lower windows 114, 116 can be transparent, e.g., to IR radiation.

The process chamber 102 further includes an outer reflector 142 and an inner reflector 144. The outer reflector 142 can be positioned around the inner reflector 144. The outer reflector 142 and the inner reflector 144 are positioned outside the upper window 114 and are arranged to reflect IR light radiating from the substrate 134 and the upper window 114 back towards the substrate 134.

The processing system 100 also includes the controller 108 for controlling processes performed by the processing system 100. The controller 108 can be any type of controller used in an industrial setting, such as a programmable logic controller (PLC). The controller 108 includes a processor 146, a memory 148, and input/output (I/O) circuits 150. The controller 108 can further include one or more of the following: power supplies, clocks, communication components (e.g., network interface card), and user interfaces typically found in controllers for semiconductor equipment.

The memory 148 can include non-transitory memory. The non-transitory memory can be used to store one or more programs and settings. The memory 148 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM))).

The processor 146 can be configured to execute various programs stored in the memory 148, such as epitaxial deposition processes. During execution of these programs, the controller 108 can communicate to I/O devices through the I/O circuits 150. For example, during execution of these programs and communication through the I/O circuits 150, the controller 108 can control outputs, such as the electric power provided to the upper and lower heating lamps 138, 140 for heating the components in the process volume 118. The memory 148 can further include various operational settings used to control the processing system 100. For example, the settings can include temperature thresholds and/or power levels for the upper heating lamps 138 and/or lower heating lamps 140 for different processes.

The process chamber 102 includes a heat transfer assembly 160. The heat transfer assembly 160 includes an upper structure 161, a lower structure 162, one or more heat pipes 163, and a heat sink 164. In one or more embodiments, the upper structure 161 and the lower structure 162 are annular rings. The lower structure 162 is disposed at least partially below the upper heating lamps 138. In one or more embodiments, the lower structure 162 is disposed outwardly of the outer reflector 142. The lower structure 162 and the outer reflector 142 are axially aligned with one another. The upper structure 161 is disposed over the lower structure 162. The upper structure 161 is disposed at least partially above the upper heating lamps 138. In one or more embodiments, the upper structure 161 is disposed outwardly of the outer reflector 142. The upper structure 161 and the outer reflector 142 are axially aligned with one another. The upper heating lamps 138 are disposed between the upper structure 161 and the lower structure 162. The upper structure 161 and the lower structure 162 are formed of a thermally conductive material, such as a metal material, such as copper or aluminum.

The upper structure 161, the lower structure 162, or a combination thereof include the one or more heat pipes 163. In one or more embodiments, the one or more heat pipes 163 are at least partially disposed within the upper structure 161 and/or the lower structure 162. In one or more embodiments, the one or more heat pipes 163 are formed of a thermally conductive metal such as copper and/or aluminum. In one or more embodiments, the one or more heat pipes 163 include an outer shell defining a vacuum-sealed volume. A heat transfer fluid is disposed within the vacuum-sealed volume. The heat transfer fluid includes liquid such as water. The one or more heat pipes 163 are coupled to the heat sink 164. The heat sink 164 can be disposed either within the processing chamber 102 or outside of the processing chamber. In one or more embodiments, the heat sink 164 is thermally connected to a cooling assembly.

During a heat transfer operation the upper structure 161 and/or the lower structure 162 are heated. The heat transfer fluid disposed within the one or more heat pipes 163 embedded within the upper structure 161 and/or the lower structure 162 absorbs heat. The heat vaporizes the heat transfer fluid. The vaporized heat transfer fluid travels to the heat sink 164. The heat sink absorbs the heat of the vaporized heat transfer fluid, which causes the heat transfer fluid to cool and condense. The condensed heat transfer fluid then flows from the heat sink 164 into the portion of the one or more heat pipes 163 disposed within the upper structure 161 and/or the lower structure 162. Thus, the one or more heat pipes 163 help cool the upper structure 161 and/or the lower structure 162. In one or more embodiments, the heat transfer fluid is contained within the vacuumed sealed volume which prevents leaks within the processing chamber 102.

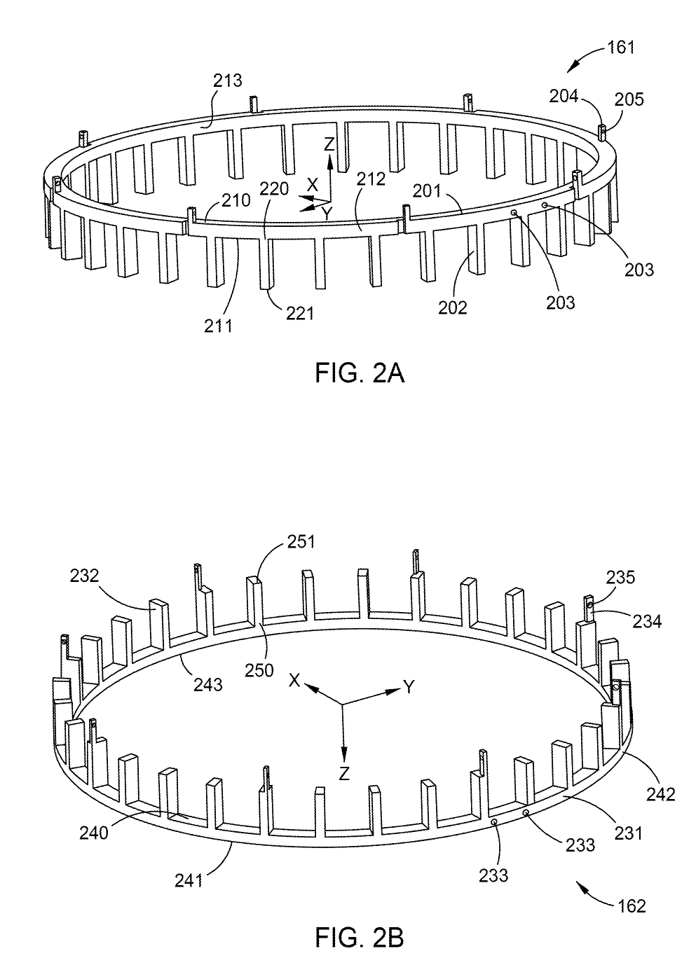

FIG. 2A is a schematic isometric view of the upper structure 161, according to one or more embodiments. The upper structure 161 includes a base 201, a plurality of upper extension structures 202, a plurality of heat pipe openings 203, and one or more flanges 204. In one or more embodiments, the base 201 is an annular ring. The base 201 includes an upper surface 210, a lower surface 211, an outer surface 212, and an inner surface 213. The plurality of upper extension structures 202 extend from the lower surface 211 of the base 201. A first end 220 of each of the upper extension structures 202 is coupled to the lower surface 211. A second end 221 of the each upper extension structure 202 extends from the lower surface 211 opposite of the first end 220.

The plurality of heat pipe openings 203 are disposed on the outer surface 212 of the base 201. The one or more flanges 204 extend from the upper surface 210 of the base 201. In one or more embodiments, each of the one or more flanges 204 include an opening 205. A fastener is configured to be disposed through the opening 205. The one or more flanges 204 are configured to couple the upper structure 161 to the processing chamber 102.

FIG. 2B is a schematic isometric view of the lower structure 162, according to one or more embodiments. The lower structure 162 includes a base 231, a plurality of lower extension structures 232, a plurality of heat pipe openings 233, and one or more flanges 234. In one or more embodiments, the base 231 is an annular ring. The base 231 includes an upper surface 240, a lower surface 241, an outer surface 242, and an inner surface 243. The plurality of lower extension structures 232 extend from the upper surface 240 of the base 231. A first end 250 of each of the lower extension structures 232 is coupled to the upper surface 240. A second end 251 of the each lower extension structure 232 extends from the upper surface 240 opposite of the first end 250.

The plurality of heat pipe openings 233 are disposed on the outer surface 242 of the base 231. The one or more flanges 234 extend from the second end 251 of one or more of the lower extension structures 232. In one or more embodiments, each of the one or more flanges 234 includes an opening 235. A fastener is configured to be disposed through the opening 235. The one or more flanges 234 are configured to couple the lower structure 162 to the upper structure 161.

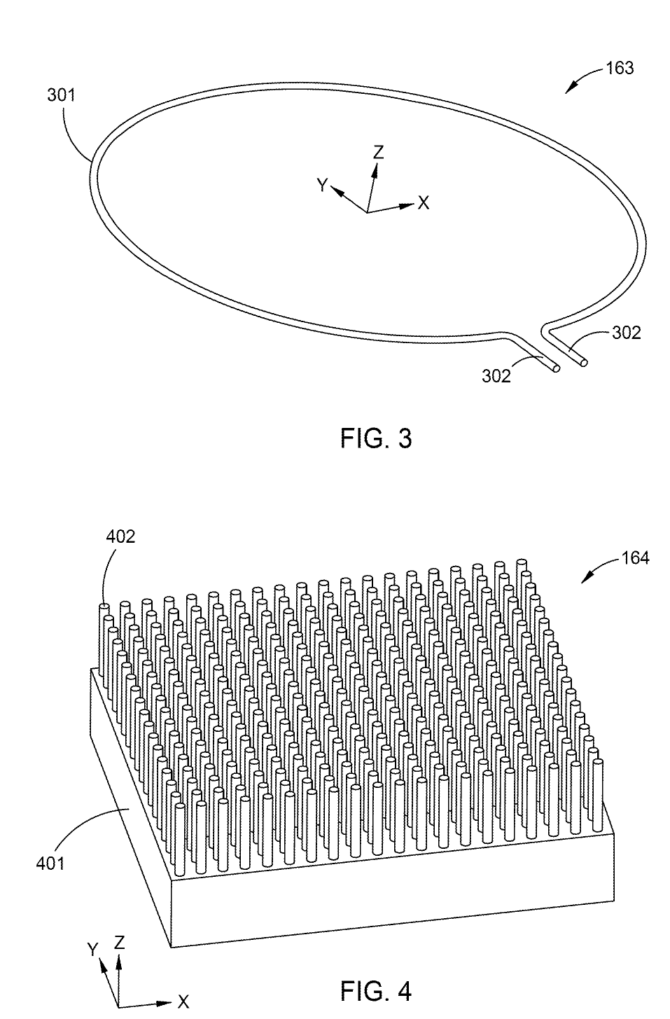

FIG. 3 is a schematic isometric view of a heat pipe 163, according to one or more embodiments. Each heat pipe 163 includes an annular portion 301 and a plurality of extension portions 302. The annular portion 301 is configured to be embedded within the base 201 of the upper structure 161 and/or the base 231 of the lower structure 162 (e.g., the annular portion 301 of one heat pipe 163 in the upper structure 161 and the annular portion 301 of another heat pipe 163 in the lower structure 162). Each extension portion 302 is configured to extend from the heat pipe openings 203 of the outer surface 212 of the upper structure 161 and/or the heat pipe openings 233 of the outer surface 242 of the lower structure 162. The extension portions 302 of the heat pipe 163 are coupled to the heat sink 164.

FIG. 4 is a schematic isometric view of the heat sink 164, according to one or more embodiments. The heat sink 164 includes a base 401 and a plurality of pillars 402. In one or more embodiments, the base 401 is formed of a conductive material. The base 401 is thermally coupled to the extension portions 302 of the one or more heat pipes 163. In one or more embodiments, at least a portion of the extension portions 302 of the one or more heat pipes 163 are embedded within the base 401. In one or more embodiments, at least a portion of the extension portions 302 of the one or more heat pipes 163 contact the base 401. The base 401 absorbs the heat of the heat transfer fluid within the one or more heat pipes 163. The plurality of pillars 402 extend from the base 401. The plurality of pillars 402 dissipate the heat absorbed by the base 401. In one or more embodiments, the pillars 402 are in contact with a cooling assembly.

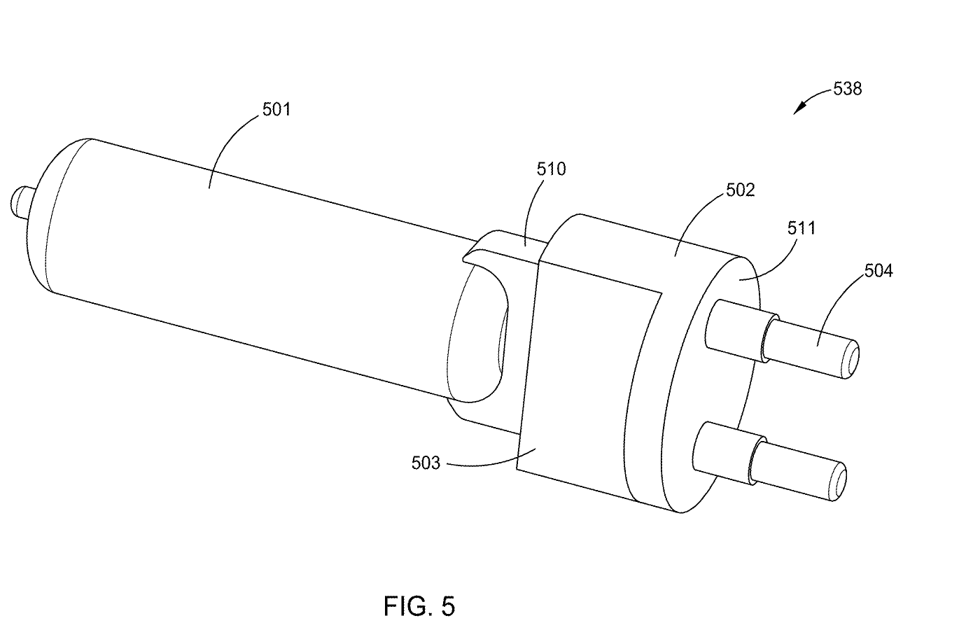

FIG. 5 is a schematic isometric view of a heating lamp 538, according to one or more embodiments. The heating lamp 538 can be used as the upper heating lamps 138 and/or the lower heating lamps 140 in the processing chamber 102. Each heating lamp 538 includes an emitting portion 501 and a base 502. During a heating operation, the emitting portion 501 emits electromagnetic radiation. A first end 510 of the base 502 is coupled to the emitting portion 501. In open or more embodiments, the base 502 includes a plurality of flat surfaces 503. A plurality of electrical connectors 504 extend from a second end 511 of the base 502. The second end 511 is disposed opposite of the first end 510. The plurality of electrical connectors 504 are configured to be electrically coupled to a power source. The plurality of electrical connectors 504 are configured to transfer the electricity of the power source to the emitting portion 501.

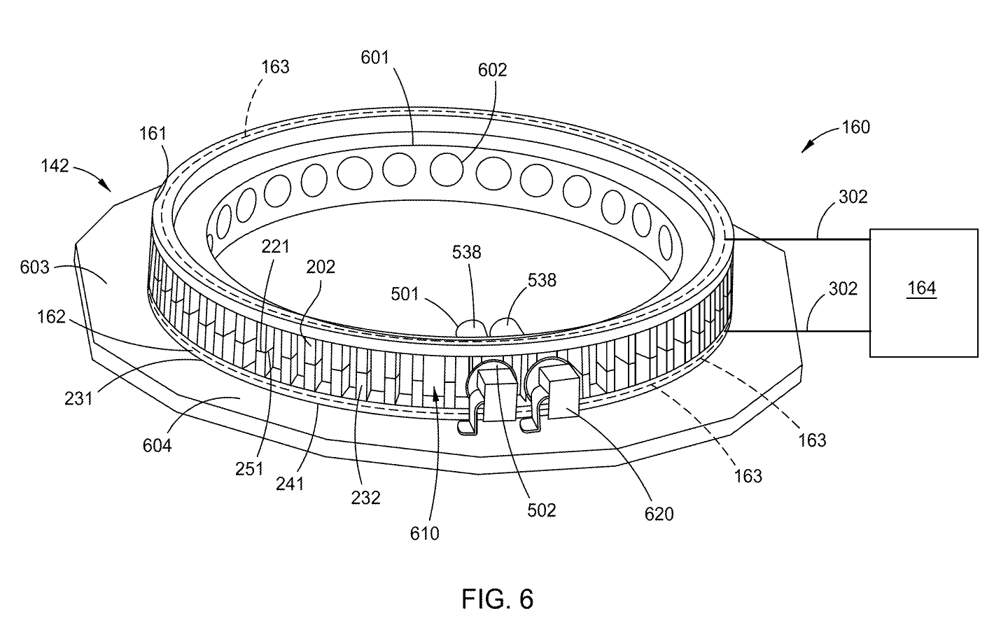

FIG. 6 is a schematic isometric view of the heat transfer assembly 160 disposed on the outer reflector 142, according to one or more embodiments. In one or more embodiments, the outer reflector 142 includes an annular portion 601. A plurality of lamp openings 602 are disposed along the annular portion 601 of the outer reflector 142. A reflector base portion 603 extends outwardly from the annular portion 601. The lower structure 162 of the heat transfer assembly 160 is disposed outwardly of the annular portion 601 of the outer reflector 142. In one or more embodiments, the lower surface 241 of the base 231 of the lower structure 162 is disposed on an upper surface 604 of the reflector base portion 603. The upper structure 161 of the heat transfer assembly 160 is disposed on the lower structure 162, outwardly of the annular portion 601 of the outer reflector 142. The upper extension structures 202 are aligned with and disposed on the lower extension structures 232 so that the second end 251 of the lower extension structures 232 contact the second end 221 of the upper extension structures 202. The lower extension structures 232 and the upper extension structures 202 define a plurality of gaps 610 between the upper structure 161 and the lower structure 162.

The heating lamps 538 are at least partially disposed through the gaps 610 and the lamp openings 602. In one or more embodiments, the emitting portion 501 extends through the lamp openings 602 so that the electromagnetic radiation emitted by the emitting portion 501 of each heating lamp 538 is emitted inwardly of the annular portion 601. In one or more embodiments, the plurality of flat surfaces 503 (FIG. 5) of each base 502 of the heating lamps 538 contact the upper extension structures 202 and/or the lower extension structures 232. In one or more embodiments, a thermal interface material is disposed between the heating lamps 538 and the extension structures 202, 232. In one or more embodiments, the heating lamps 538 directly contact the extension structures 202, 232. In one or more embodiments, a support structure 620 is coupled to the second end 511 (FIG. 5) of the base 502 of each of the heating lamps 538. In one or more embodiments, the support structures 620 are coupled to the reflector base portion 603. The support structures are electrically connected to a power source and configured to supply a power to the heating lamps 538. Although FIG. 6 is shown including two of the heating lamps 538, it should be understood that any number of heating lamps 538 can be used, for example, one heating lamp 538, two heating lamps 538, four heating lamps 538, ten heating lamps 538, or twenty heating lamps 538.

One or more heating pipes 163 are disposed within the upper structure 161, the lower structure 162, or a combination thereof. The extension portions 302 of the one or more heat pipes 163 are connected to the heat sink 164. In one or more embodiments, the heat sink 164 is disposed on the upper surface 604 of the reflector base portion 603. In one or more embodiments, the heat sink 164 is disposed outwardly of the processing chamber 102 (FIG. 1). Although FIG. 6 is shown including one heat sink 164, it is contemplated that any number of heat sinks 164 can be used.

During a heating operation the heating lamps 538 generate heat. Some of the heat generated by the heating lamps 538 is transferred from the heating lamps 538 to the upper structure 161, the lower structure 162, or a combination thereof. In one or more embodiments, the upper structure 161 and/or the lower structure 162 contact the base 502 of each heating lamp 538. The heat generated by the heating lamps 538 is conducted through the upper structure 161 and/or the lower structure 162 and is absorbed by the heat transfer fluid within the one or more heat pipes 163. The one or more heat pipes 163 transmit the heat to the heat sink 164. The heat sink 164 dissipates the heat. Thus, the heat transfer assembly 160 cools the heating lamps 538 and prevents the heating lamps 538 from overheating and getting damaged.

Although the heat transfer assembly 160 is described being disposed around the outer reflector 142 it should be understood that in one or more embodiments, the heat transfer assembly 160 may be disposed below the lower window 116 around the shaft 128.In one or more embodiments, the lower heating lamps 140 are disposed through the gaps 610 of the heat transfer assembly. In one or more embodiments, the heat transfer assembly is used to cool the upper heating lamps, the lower heating lamps 140, or a combination thereof.

Embodiments of the present disclosure include a heat transfer assembly for the heating lamps. The heating lamps include the upper heating lamps, the lower heating lamps, or a combination thereof. The heat transfer assembly cools the heating lamps and prevents the heating lamps from overheating and getting damaged. The heat transfer fluid within the one or more heat pipes is sealed which prevents the heat transfer fluid from leaking within the processing chamber.

It is contemplated that one or more aspects disclosed herein may be combined. As an example, one or more aspects, features, components, operations and/or properties of the processing system 100, the processing chamber 102, the housing structure 110, the quartz chamber 112, the substrate support assembly 124, the gas sources 104, the exhaust pump 106, the upper heating lamps 138, the lower heating lamps 140, the controller 108, the heat transfer assembly 160, the upper structure 161, the lower structure 162, the one or more heat pipes 163, and/or the heat sink 164 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
a housing structure;
an upper window and a lower window disposed within the housing structure, the upper window and the lower window at least partially defining a processing volume;
a reflector disposed within the housing structure outside of the processing volume;
a heat transfer assembly disposed outwardly of an annular portion of the reflector, the heat transfer assembly comprising:
a lower structure disposed on a base portion of the reflector;
an upper structure disposed on the lower structure;
one or more heat pipes disposed within the upper structure, the lower structure, or a combination thereof; and
a heat sink coupled to the one or more heat pipes; and
one or more heating lamps contacting the heat transfer assembly.

2. The processing chamber of claim 1, wherein the lower structure comprises:
a base comprising a first surface and a second surface disposed opposite the first surface; and
a plurality of lower extension structures extending from the second surface;
wherein the upper structure comprises:
a base comprising a first surface and a second surface disposed opposite the first surface; and
a plurality of upper extension structures extending from the second surface.

3. The processing chamber of claim 2, wherein the upper extension structures are aligned with and disposed on the lower extension structures.

4. The processing chamber of claim 2, wherein the one or more heat pipes are at least partially disposed within the base of the upper structure, the base of the lower structure, or a combination thereof.

5. The processing chamber of claim 4, wherein the plurality of upper extension structures and the plurality of lower extension structures define gaps.

6. The processing chamber of claim 5, wherein the one or more heating lamps extend through the gaps.

7. The processing chamber of claim 1, wherein the upper structure and the lower structure are formed of a thermally conductive material.

8. The processing chamber of claim 7, wherein the thermally conductive material comprises copper.

9. The processing chamber of claim 1, wherein the one or more heat pipes each comprise an outer shell defining a vacuum-sealed volume and a heat transfer fluid disposed within the vacuum-sealed volume.

10. The processing chamber of claim 1, wherein the lower structure and the upper structure are annular rings.

11. A heat transfer assembly comprising:
a lower structure comprising:
an annular base; and
a plurality of lower extension structures extending from the annular base;
an upper structure comprising:
an annular base; and
a plurality of upper extension structures extending from the annular base;
one or more heat pipes comprising:
an annular portion disposed within the annular base of the lower structure, the annular base of the upper structure, or a combination thereof; and
an extension portion disposed outwardly of the lower structure, the upper structure, or a combination thereof; and
a heat sink coupled to the extension portion.

12. The heat transfer assembly of claim 11, wherein the upper extension structures are aligned with and disposed on the lower extension structures.

13. The heat transfer assembly of claim 12, wherein the plurality of upper extension structures and the plurality of lower extension define gaps.

14. The heat transfer assembly of claim 11, wherein the upper structure and the lower structure are formed of a thermally conductive material.

15. The heat transfer assembly of claim 14, wherein the thermally conductive material comprises copper.

16. The heat transfer assembly of claim 11, wherein the one or more heat pipes further comprise an outer shell defining a vacuum-sealed volume and a heat transfer fluid disposed within the vacuum-sealed volume.

17. The heat transfer assembly of claim 11, wherein the heat sink comprises a base and a plurality of pillars disposed on the base.

18. A processing chamber, comprising:
a housing structure;
an upper window and a lower window disposed within the housing structure, the upper window and the lower window at least partially defining a processing volume;
a reflector disposed within the housing structure outside of the processing volume;
a heat transfer assembly disposed outwardly of an annular portion of the reflector, the heat transfer assembly comprising:
a lower structure comprising:
an annular base; and
a plurality of lower extension structures extending from the annular base;
an upper structure comprising:
an annular base; and
a plurality of upper extension structures extending from the annular base;
one or more heat pipes comprising:
an annular portion disposed within the annular base of the lower structure, the annular base of the upper structure, or a combination thereof; and
an extension portion disposed outwardly of the lower structure, the upper structure, or a combination thereof; and
a heat sink coupled to the extension portion; and
one or more heating lamps contacting the heat transfer assembly.

19. The processing chamber of claim 18, wherein the one or more heat pipes further comprise an outer shell defining a vacuum-sealed volume and a heat transfer fluid disposed within the vacuum-sealed volume.

20. The processing chamber of claim 18, wherein the one or more heating lamps extend through gaps defined by the plurality of upper extension structures and the plurality of lower extension structures.
